(19) United States
(12) Patent Application Publication
(10) Pub. No.: US 2012/0161827 A1
(43) Pub. Date: Jun. 28, 2012

(54) CENTRAL LC PLL WITH INJECTION LOCKED RING PLL OR DELL PER LANE

(75) Inventors: Paul Madeira, Ottawa (CA); John Hogeboom, Ottawa (CA); Pat Hogeboom-Nivera, Ottawa (CA)

(73) Assignee: STMicroelectronics (Canada) Inc., Nepean (CA)

(21) Appl. No.: 13/338,111

(22) Filed: Dec. 27, 2011

Related U.S. Application Data
(60) Provisional application No. 61/427,635, filed on Dec. 28, 2010.

(51) Int. Cl. H03L 7/08

(52) U.S. Cl. 327/147

(57) ABSTRACT

A clock circuit includes a frequency or phase comparator for receiving a reference clock signal, an LC VCO coupled to the comparator, a feedback divider coupled between the LC VCO and the comparator, a clock distribution chain coupled to the feedback divider and the first VCO, and a DLL or injection-locked ring-VCO coupled to the clock distribution chain for providing a plurality of phased output clock signals.

### RELATED APPLICATION

The present invention claims priority from U.S. Provisional Patent Application Ser. No. 61/427,635 filed Dec. 28, 2010, and is incorporated herein by reference in its entirety for all purposes as if fully set forth herein.

### BACKGROUND OF THE INVENTION

The present invention relates to clock circuits, and more particularly clock circuit used with Serializer/Deserializer (SerDes) circuits.

High data-rate SerDes circuits often use a multi-phase clock source to allow phase to be accurately and rapidly manipulated by digital means when needed, while otherwise maintaining very low phase noise. One way this can be achieved is by using a common, central, low noise, multi-phase clock source to divide the relatively large clock power needed to achieve low phase noise, over many lanes. However, it is not possible to simultaneously provide various data rates for each lane independent of other lanes, and it takes extra power for the clock bus to span the entire lane width rather than just the essential portion where connections are needed. On the other hand, if separate, local, low-noise, multi-phase VCOs are used for each lane, each requires much higher power to achieve low phase noise. By injecting a reference clock of low phase noise and limited but significant amplitude into a local multiphase (ring) oscillator, that oscillator can copy the low phase noise of the injected signal and achieve wide operating frequency range with much reduced power consumption. Essentially, the recirculated component of the signal present on the local clock nodes of the ring oscillator is replaced by a significant level of injected reference signal, so the noise generated within the ring undergoes much less regeneration. A roughly equivalent variation is to employ a DLL configuration by opening a nearly identical ring at the injection point to form a delay chain, making the injection stage identical to each ring stage, and loading the last stage of the delay to match the other stages. In this case, there is no noise multiplication but potentially some variation in phase spacing and waveform between the multiple phases. Either variation makes it practical to implement many low-power, long-reach, SerDes communication lanes of selectable data-rate in a relatively small area of an ASIC.

With either variation, several low phase noise, high rate, i.e., bit-rate or one-half bit-rate, reference clocks need to be generated within the ASIC to drive the multiple injection locked PLLs or DLLs. To do this, the most effective and practical scheme is to use LC PLLs with relatively high Q LC tanks which achieve low noise and jitter due to their narrow bandwidth being achieved passively rather than by regenerative electronic means. Such LC PLLs can achieve very low noise due to their passive high Q tanks and increased power available by being shared over many lanes. These LC PLLs also perform an important frequency synthesis function, allowing various much lower frequency system reference clocks to precisely control all of the operating rates of SerDes lanes.

Most or many high data-rate SerDes have the problems described above, and usually resort to diminished capability or increased power consumption. They may use a common high power clock source and distribution bus, allowing acceptable power but just one primary rate for all lanes in each block. They may distribute two or more complete multi-phase clock buses to all SerDes lanes resulting in significant power increase. They may also use much increased power by including separate low-noise analog PLLs for each lane. They may also be very restricted in acceptable reference clock frequencies rather than being able to accept a wide range of reference frequencies.

A typical SerDes clocking strategy is implemented by circuit 100 shown in FIG. 1. Circuit 100 includes a 125 MHz reference clock, a phase or frequency comparator 102, a feedback divider circuit 104, and a 6.25 GHz ring VCO 106 for providing a plurality of phased output signals 108.

Ring VCOs have large frequency range and high gain and so generate high phase-noise. A good reference clock and high PLL loop bandwidth are needed for acceptable VCO phase-noise. The high PLL loop bandwidth transfers most reference clock phase-noise to the outputs.

Eight phases are provided in the plurality of output signals 108 to be used by a 12.5 Gb/s SerDes phase interpolator for per-lane phase/frequency tracking control.

Ring VCO 106 must be physically large to reduce phase-noise, so should be physically distributed and shared by many lanes to limit average power-per-lane.

What is desired is a circuit solution that solves all of the above problems with the prior art circuits.

### SUMMARY OF THE INVENTION

According to the present invention, a clock circuit comprises a frequency or phase comparator for receiving a reference clock signal, a LC VCO coupled to the comparator, a feedback divider coupled between the LC VCO and the comparator, a clock distribution chain coupled to the feedback divider and the first VCO, and a DLL or injection-locked ring-VCO coupled to the clock distribution chain for providing a plurality of phased output clock signals.

The comparator comprises a frequency or phase comparator, the reference clock signal comprises a 125 MHz reference clock signal. The first VCO comprises a 6.25 GHz LC VCO. The feedback divider can comprise a divide by 50 feedback divider. The clock distribution chain comprises a single phase clock distribution chain including a plurality of buffer circuits. The second VCO comprises a plurality of VCOs for providing a plurality of multiple phase output clock signals. The second VCO comprises a DLL or an injection-locked ring-VCO.

### BRIEF DESCRIPTION OF THE DRAWINGS

FIG. 1 is a schematic diagram of a prior art clock circuit; and

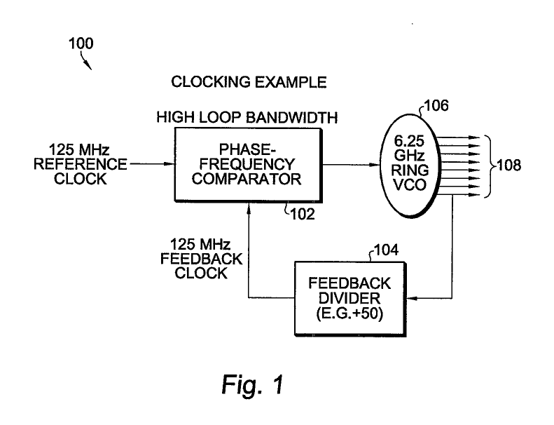

FIG. 2 is a schematic diagram of a clock circuit according to the present invention.

### DETAILED DESCRIPTION

A clocking circuit according to the present invention solves the problem of implementing ASIC circuit blocks requiring many multiphase, low-noise, low-power clock sources, each independently able to operate at one of multiple centrally regulated frequencies. One primary application is for implementing many SerDes lanes in a single ASIC.

An improved SerDes clocking strategy according to the present invention includes the following elements:

LC VCOs have high passive EM energy storage and low gain, hence, low phase-noise;

Low phase-noise can be achieved even with low LC PLL loop bandwidth, which helps to also reduce Reference Clock phase-noise transfer to outputs;

The high bandwidth of injection locking transfers the low LC noise to the range VCOs; and

Single-phase distribution reduces power and area and allows per-lane rate choices.

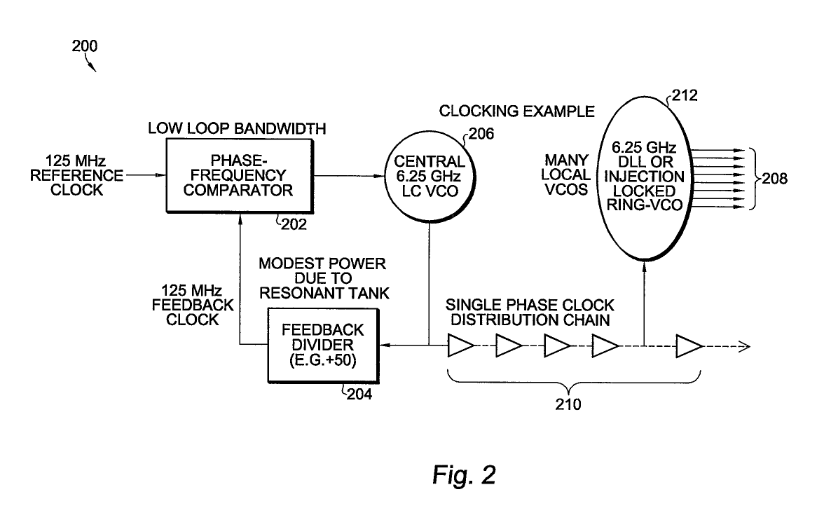

Referring now to FIG. 2, clocking circuit 200 according to an embodiment of the invention includes a 125 MHz reference clock, a phase-frequency comparator 202, a feedback divider 204 (e.g. +50), and a central 6.25 GHz LC VCO 206 in a loop configuration. The loop has low loop bandwidth, and uses modest power due to the use of a resonant tank. The feedback divider 204 provides a 125 MHz feedback clock signal to the phase-frequency comparator 202. A single phase clock distribution chain 210 is coupled to the junction between VCO 206 and divider 204. The clock distribution chain comprises a plurality of serially coupled buffer stages. A plurality of local VCOs represented by VCO 212 provides a plurality of phased output clock signals 208. Each local VCO 212 can be a 6.25 GHz Delay-Locked Loop (“DLL”) or Injection Locked Ring-VCO. The eight phases provided at output 208 can be used by 12.5 Gb/s SerDes phase interpolator for per-lane phase/frequency tracking control.

The ring VCO 212 can be small and independent for each lane. Injection locking is not a feedback process; it is a simple mixing process with no separate bandwidth limit.

Multi-lane SerDes with relatively high flexibility in allowing different and multiple simultaneous data rates amid various reference clock frequencies, can use local, multiphase, injection-locked Ring PLLs or DLLs per lane combined with central LC PLLs as taught according to the present invention.

In conclusion a clock circuit according to the present invention includes a phase or frequency comparator 202 for receiving a reference 125 MHz reference clock signal, a first VCO 206 coupled to the comparator, wherein the first VCO is a first type of VCO circuit (2.25 GHz LC VCO), a feedback divider (divide by 50) coupled between the first VCO and the comparator, a clock distribution chain 210 coupled to the feedback divider and the first VCO, and a second VCO 212 coupled to the clock distribution chain for providing an output clock signal, wherein the second VCO is a second type of VCO circuit (plurality of 6.25 GHz DLL or Injection-Locked Ring VCOs).

Although a specific circuit embodiment of the invention has been disclosed along with certain alternatives (implementation may be effectuated using hardware components, firmware components, or software components, or combinations thereof; frequencies and divider value may be changed as required for a particular application), it will be recognized by those skilled in the art that additional variations in form and detail may be made within the scope of the following claims

We claim:

1. A clock circuit comprising:
a comparator for receiving a reference clock signal;
a first VCO coupled to the comparator;
a feedback divider coupled between the first VCO and the comparator;
a clock distribution chain coupled to the feedback divider and the first VCO; and
a second VCO coupled to the clock distribution chain for providing an output clock signal.

2. The clock circuit of claim 1 wherein the comparator comprises a frequency comparator.

3. The clock circuit of claim 1 wherein the comparator comprises a phase comparator.

4. The clock circuit of claim 1 wherein the reference clock signal comprises a 125 MHz reference clock signal.

5. The clock circuit of claim 1 wherein the first VCO comprises an LC VCO.

6. The clock circuit of claim 1 wherein the first VCO comprises a 6.25 GHz VCO.

7. The clock circuit of claim 1 wherein the feedback divider comprises a divide by 50 feedback divider.

8. The clock circuit of claim 1 wherein the clock distribution chain comprises a single phase clock distribution chain including a plurality of buffer circuits.

9. The clock circuit of claim 1 further comprising the second VCO comprises a plurality of VCOs for providing a plurality of multiple phase output clock signals.

10. The clock circuit of claim 1 wherein the second VCO comprises a DLL or an injection-locked ring-VCO.

11. A clock circuit comprising:
a comparator for receiving a reference clock signal;
a first VCO coupled to the comparator, wherein the first VCO is a first type of VCO circuit;
a feedback divider coupled between the first VCO and the comparator;
a clock distribution chain coupled to the feedback divider and the first VCO; and
a second VCO coupled to the clock distribution chain for providing an output clock signal, wherein the second VCO is a second type of VCO circuit.

12. The clock circuit of claim 11 wherein the comparator comprises a frequency comparator.

13. The clock circuit of claim 11 wherein the comparator comprises a phase comparator.

14. The clock circuit of claim 11 wherein the reference clock signal comprises a 125 MHz reference clock signal.

15. The clock circuit of claim 11 wherein the first VCO comprises an LC VCO.

16. The clock circuit of claim 11 wherein the first VCO comprises a 6.25 GHz VCO.

17. The clock circuit of claim 11 wherein the feedback divider comprises a divide by 50 feedback divider.

18. The clock circuit of claim 11 wherein the clock distribution chain comprises a single phase clock distribution chain including a plurality of buffer circuits.

19. The clock circuit of claim 11 further comprising the second VCO comprises a plurality of VCOs for providing a plurality of multiple phase output clock signals.

20. The clock circuit of claim 11 wherein the second VCO comprises a DLL or an injection-locked ring-VCO.

21. A method of providing a plurality of phased clock signals comprising:
comparing a reference clock signal to a feedback signal;
transferring a result of the comparison to a first VCO;
dividing an output signal provided by the first VCO to generate the feedback signal; and
providing the output signal to a plurality of second VCOs to generate the plurality of phased clock signals, wherein the first VCO and second VCO are different types of VCO circuits.
